(19) United States
(12) Patent Application Publication
(10) Pub. No.: US 2026/0341324 A1
(43) Pub. Date: Oct. 29, 2026

(54) MAGNETIC MEMORY DEVICE AND METHOD FOR OPERATING THE SAME

(71) Applicant: Samsung Electronics Co., Ltd., Suwon-si (KR)

(72) Inventors: Dae Shik KIM, Suwon-si (KR); Gyu Seong KANG, Suwon-si (KR); Kyoung Ho KIM, Suwon-si (KR); Ji Hun BYUN, Suwon-si (KR); Hyun-Jin SHIN, Suwon-si (KR)

(21) Appl. No.: 19/450,987

(22) Filed: Jan. 16, 2026

(30) Foreign Application Priority Data
Apr. 24, 2025 (KR) 10-2025-0053835

(51) Int. Cl. G11C 11/16; G11C 17/02

(52) U.S. Cl. CPC G11C 11/1675; G11C 11/161; G11C 11/1657; G11C 11/1673; G11C 17/02

(57) ABSTRACT

Provided is a method for operating a magnetic memory device. The method for operating a magnetic memory device according to some embodiments of the present disclosure includes applying a first word line voltage to an OTP cell to perform a write operation thereon, wherein the OTP cell is connected to a first word line and a bit line and includes a first magnetic tunnel junction element and an OTP cell transistor, applying a second word line voltage to the OTP cell to perform a read operation thereon, and in order to perform the write operation, applying a third word line voltage different from the second word line voltage to a plurality of second word lines different from the first word line.

### CROSS-REFERENCE TO RELATED APPLICATION

This application claims priority from Korean Patent Application No. 10-2025-0053835 filed on Apr. 24, 2025 in the Korean Intellectual Property Office, and all the benefits accruing therefrom under 35 U.S.C. 119, the contents of which in its entirety are herein incorporated by reference.

### TECHNICAL FIELD

The present disclosure relates to a magnetic memory device and a method for operating the same.

### BACKGROUND

As an electronic device becomes faster and less power-consuming, a magnetic memory device embedded therein also requires fast read/write operations and low operating voltage. A magnetic memory device is being studied as a magnetic memory device that satisfies these requirements. The magnetic memory device is nonvolatile and capable of high-speed operation, and thus is receiving attention as a next-generation memory.

As the magnetic memory device becomes increasingly highly integrated, Spin-Transfer Torque Magnetic Random Access Memory (STT-MRAM) which stores information using the Spin Transfer Torque (STT) phenomenon, is being studied. The STT-MRAM may store information by directly applying current to a magnetic tunnel junction element to induce magnetization reversal. The highly integrated STT-MRAM requires high-speed operation and low-current operation.

In one example, a One-Time-Programmable (OTP) memory is a nonvolatile memory in which data is permanently maintained upon a single program. The OTP memory is generally used for the purpose of recording specific information only once and allowing the information to be read continuously, and may be used in applications where data stability and security are important. Since the OTP memory may be programmed only once, information therein cannot be changed, thereby ensuring data integrity and stability. The OTP memory is mainly used in applications that require reliability and security. For example, the OTP memory is used to store therein information such as digital security tokens, smart cards, keys and passwords, booting codes, and production/manufacturing settings, and may be embedded as a portion of a semiconductor chip therein or may be provided as an independent chip. When the OTP memory is embedded as the portion of the chip, the OTP memory may be implemented at low cost and thus may be usefully used without affecting performance of a core logic as long as the OTP is fully compatible with a logic CMOS process.

### SUMMARY

A technical objective of the present disclosure is to provide a method for operating a magnetic memory device with improved product reliability.

The objectives according to the present disclosure are not limited to the above-mentioned purpose. Other objectives and advantages according to the present disclosure that are not mentioned may be understood based on following descriptions, and may be more clearly understood based on embodiments according to the present disclosure. Further, it will be easily understood that the objectives and advantages according to the present disclosure may be achieved using technical solutions shown in the claims and combinations thereof.

A method for operating a magnetic memory device according to some embodiments of the present disclosure includes applying a first word line voltage to an OTP cell to perform a write operation thereon, wherein the OTP cell is connected to a first word line and a bit line and includes a first magnetic tunnel junction element and an OTP cell transistor, applying a second word line voltage to the OTP cell to perform a read operation thereon, and in order to perform the write operation, applying a third word line voltage different from the second word line voltage to a plurality of second word lines different from the first word line.

A method for operating a magnetic memory device according to some other embodiments of the present disclosure includes applying a first word line voltage to an OTP cell to perform a write operation thereon, wherein the OTP cell is connected to a selected word line among word lines and a bit line and includes a first magnetic tunnel junction element and an OTP cell transistor, applying a second word line voltage to the OTP cell to perform a read operation thereon, providing a first voltage to a dummy cell including a second magnetic tunnel junction element and a dummy cell transistor, applying a third word line voltage to unselected word lines different from the selected word line among the word lines, wherein the third word line voltage is a voltage trimmed based on a gate-induced drain leakage (GIDL) of the dummy cell transistor.

A method for operating a magnetic memory device according to some embodiments of the present disclosure includes applying a first word line voltage to an OTP cell to perform a write operation thereon, wherein the OTP cell is connected to a selected word line among word lines and a bit line and includes a first magnetic tunnel junction element and an OTP cell transistor, and turning on a first switch to apply a second word line voltage to the OTP cell to perform a read operation thereon, wherein the performing of the write operation includes turning on a second switch to generate a third word line voltage different from the second word line voltage, and applying the third word line voltage to unselected word lines different from the selected word line among the word lines.

A magnetic memory device according to some embodiments of the present disclosure includes a memory cell array including an OTP cell and a memory cell, and a peripheral circuit electrically connected to each of the OTP cell and the memory cell and configured to provide a trimmed word line voltage to the memory cell array, wherein the OTP cell is connected to a first word line and a bit line and includes a first magnetic tunnel junction element and an OTP cell transistor connected to the first word line, wherein the memory cell is connected to a second word line and the bit line, and includes a second magnetic tunnel junction element, and a memory cell transistor connected to the second word line, wherein the peripheral circuit includes a dummy cell array including a third magnetic tunnel junction element and a dummy cell transistor, a voltage providing unit configured to provide a first voltage to the dummy cell array, a current-voltage converter configured to generate a second voltage based on a gate-induced drain leakage (GIDL) of the dummy cell transistor, a comparator configured to compare the second voltage with a reference voltage and generate the second voltage lower than the reference voltage as an output voltage, and a word line voltage generator configured to generate the trimmed word line voltage based on the output voltage.

Specific details of some embodiments are included in the detailed description and drawings.

### BRIEF DESCRIPTION OF DRAWINGS

Aspects and features of the present disclosure will become more apparent by describing in detail illustrative embodiments thereof with reference to the attached drawings, in which:

FIG. 1 is a block diagram for illustrating an electronic device according to some embodiments;

FIG. 2 is a block diagram for illustrating a magnetic memory device according to some embodiments;

FIG. 3 is an example circuit diagram for illustrating a magnetic memory device according to some embodiments;

FIG. 4 is an example diagram for illustrating a magnetic memory device according to some embodiments;

FIG. 5 is an example circuit diagram for illustrating a memory unit cell according to some embodiments;

FIG. 6 is an example circuit diagram for illustrating an OTP unit cell according to some embodiments;

FIG. 7 is a diagram for illustrating resistances of a memory unit cell and an OTP unit cell according to some embodiments;

FIGS. 8 and 9 are schematic diagrams for illustrating GIDL characteristics of a magnetic memory device according to some embodiments;

FIG. 10 is an example circuit diagram for illustrating a dummy cell according to some embodiments;

FIGS. 11 and 12 are example diagrams for illustrating a magnetic memory device according to some embodiments;

FIG. 13 is an example circuit diagram for illustrating a magnetic memory device according to some embodiments;

FIG. 14 is an example circuit diagram for illustrating a magnetic memory device according to some embodiments;

FIG. 15 is a flowchart illustrating a method for operating a magnetic memory device according to some embodiments.

### DETAILED DESCRIPTIONS

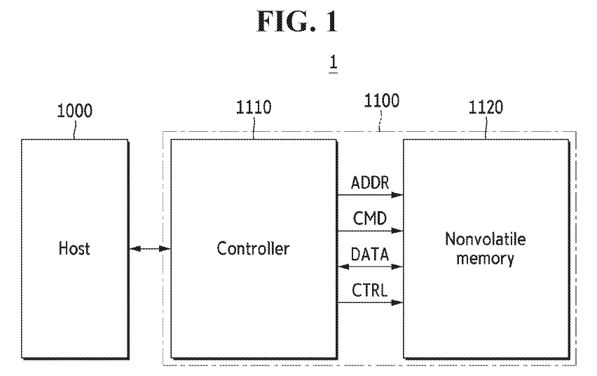

FIG. 1 is a block diagram for illustrating an electronic device according to some embodiments.

Referring to FIG. 1, the electronic device 1 may include a host 1000 and a magnetic memory device 1100. In some embodiments, the host 1000 may be connected to the magnetic memory device 1100 via an interface. For example, the host 1000 may transmit a signal to the magnetic memory device 1100 to control the magnetic memory device 1100. Furthermore, for example, the host 1000 may receive a signal from the magnetic memory device 1100 and process data included in the signal.

For example, the host 1000 may include a central processing unit (CPU), a controller, or an application specific integrated circuit (ASIC). Furthermore, for example, the host 1000 may include a memory chip such as Dynamic Random Access Memory (DRAM), Static RAM (SRAM), Phase-change RAM (PRAM), Magnetoresistive RAM (MRAM), Ferroelectric RAM (FeRAM), and Resistive RAM (ReRAM).

The magnetic memory device 1100 may include a controller 1110 and a nonvolatile memory 1120.

The controller 1110 may write data DATA to the nonvolatile memory 1120 or read the data DATA stored in the nonvolatile memory 1120 according to a request from an external device (e.g., a host, an AP, etc.). For example, the controller 1110 may transmit an address ADDR, a command CMD, and a control signal CTRL to the nonvolatile memory 1120 in order to write the data DATA to the nonvolatile memory 1120 or to read the data DATA stored in the nonvolatile memory 1120.

The nonvolatile memory 1120 may exchange the data DATA with the controller 1110 in response to signals received from the controller 1110. For example, the nonvolatile memory 1120 may include MRAM, PRAM, RRAM, etc.

However, embodiments according to the technical idea of the present disclosure are not limited thereto. The nonvolatile memory 1120 is not limited to a resistive memory and may include various nonvolatile memories such as Electrically Erasable and Programmable ROM (EPROM), flash memory, and FeRAM.

The controller 1110 and the nonvolatile memory 1120 may be connected to each other via an interface. The controller 1110 may access the nonvolatile memory 1120. For example, the controller 1110 may control read, write, and erase operations on the nonvolatile memory 1120. The controller 1110 may serve as an interface between the host 1000 and the nonvolatile memory 1120. The controller 1110 may drive firmware for controlling the nonvolatile memory 1120.

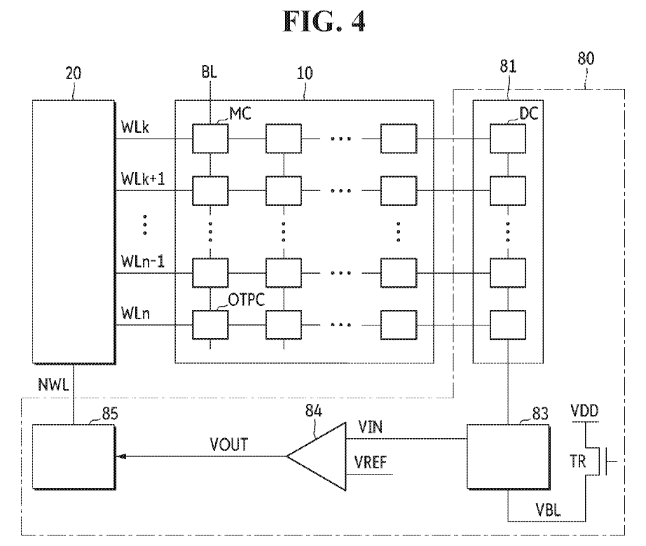

Although not specifically shown, the controller 1110 may include a reference voltage setting unit (not shown) for setting a reference voltage (VREF of FIG. 4) based on allowable leakage currents (e.g., GIDL) of cell transistors to be described later. The reference voltage setting unit (not shown) may perform a test on the memory device to set the reference voltage (VREF of FIG. 4). The reference voltage setting unit (not shown) may generate the data DATA in the process of performing the test and transmit the generated data DATA to the nonvolatile memory 1120. For example, the data DATA may include information about the reference voltage VREF (see FIG. 4).

Although not specifically shown, the controller 1110 may further include a buffer (not shown). The buffer (not shown) may temporarily store therein data provided from, for example, the components of the controller 1110, that is, the host 1000, and the nonvolatile memory 1120. Furthermore, the buffer (not shown) may provide the temporarily stored data to the components of the controller 1100, that is, the host 1000, and the nonvolatile memory 1120. For example, the buffer (not shown) may include, but is not limited to, a volatile memory such as DRAM, SRAM, or may include a nonvolatile memory such as flash memory, PRAM, MRAM, ReRAM, and FeRAM.

An example in which the buffer (not shown) is included in the controller 1110 is described above. However, embodiments according to a technical concept of the present disclosure are not limited thereto, and the buffer (not shown) may be included in the nonvolatile memory 1120.

The interface between the host 1000 and the magnetic memory device 1100 may include various communication standards, such as Universal Serial Bus (USB), multimedia card (MMC), peripheral component interconnection (PCI), PCI-express (PCI-E), Advanced Technology Attachment (ATA), Serial-ATA, Parallel-ATA, small computer small interface (SCSI), enhanced small disk interface (ESDI), Integrated Drive Electronics (IDE), and Firewire.

The magnetic memory device 1100 may include a PC card (e.g., personal computer memory card international association (PCMCIA), a compact flash card (CF), a smart media card (SM, SMC), a memory stick, a multimedia card (MMC, RS-MMC, MMCmicro), an SD card (SD, miniSD, microSD, SDHC), a universal flash magnetic memory device (UFS), etc. In addition, the magnetic memory device 1100 may include a solid-state drive (SSD) integrated into a single semiconductor device.

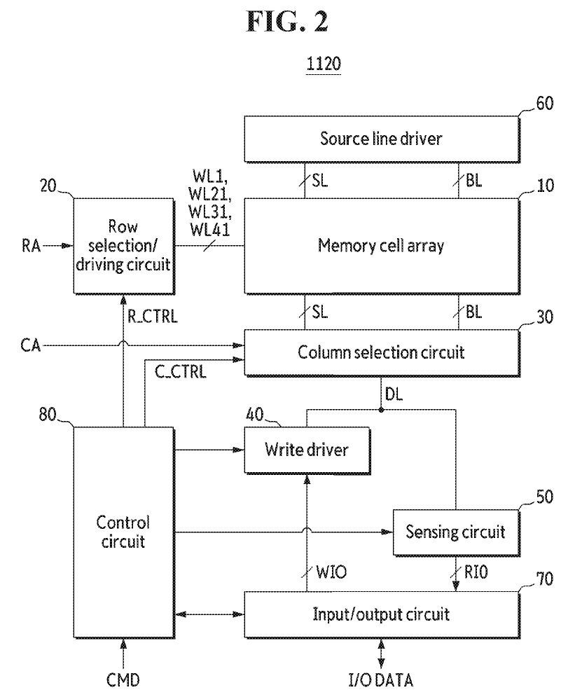

FIG. 2 is a block diagram for illustrating a magnetic memory device according to some embodiments.

Referring to FIG. 2, the nonvolatile memory 1120 according to some embodiments may include a memory cell array 10, a row selection/driving circuit 20, a column selection circuit 30, a write driver 40, a sensing circuit 50, a source line driver 60, an input/output circuit 70, and a control circuit 80.

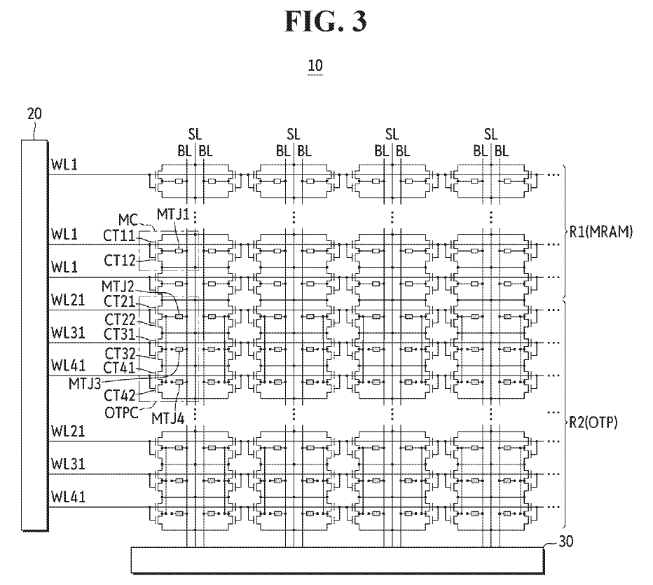

The memory cell array 10 may include a plurality of word lines WL1, WL21, WL31, and WL41, a plurality of bit lines BL, and source lines SL. Memory cells (e.g., the memory unit cell MC and the OTP unit cell OTPC of FIG. 3) may be connected to points where the word lines WL1, WL21, WL31, and WL41 and the bit lines BL intersect each other. Each of the memory cells may be configured to store data therein. The memory cell may include, for example, a variable resistance element in which a value of stored data is determined based on a resistance value, such as a magnetic tunnel junction (MTJ) element.

For example, the memory cell may include ReRAM, PRAM, FeRAM, etc., or may include MRAM such as Spin-Transfer Torque Magnetic Random Access Memory (STT-MRAM), Spin Torque Transfer Magnetization Switching RAM (Spin-RAM), and Spin Momentum Transfer RAM (SMT-RAM).

The row selection/driving circuit 20 may select (or drive) a word line WL1, WL21, WL31, or WL41 connected to a memory cell on which a read operation or a program operation is performed, based on a row address RA and a row control signal R_CTRL. The row selection/driving circuit 20 may provide a driving voltage input from the control circuit 80 to the selected word line.

The column selection circuit 30 may select a bit line BL and/or a source line SL connected to a memory cell on which a read operation or a program operation is performed, based on a column address CA and a column control signal C_CTRL. The column selection circuit 30 may connect the selected bit line BL and source line SL to a data line DL.

The write driver 40 may apply a program voltage (or write current) to the memory cell selected by the row selection/driving circuit 20 and the column selection circuit 30 to store write data therein during a program operation. For example, during the program operation, the write driver 40 may control a voltage of the data line DL based on write data I/O DATA input from the input/output circuit 70 through a write input/output line WIO to store the write data I/O DATA in the selected memory cell.

During a read operation, the sensing circuit 50 may detect a signal output through the data line DL and determine a value of the data stored in the memory cell based on the detected signal. The sensing circuit 50 may be connected to the column selection circuit 30 via the data line DL and to the input/output circuit 70 via a read input/output line RIO. The sensing circuit 50 may input detected read data I/O DATA to the input/output circuit 70 via the read input/output line RIO.

The source line driver 60 may apply a specific voltage level to the source line SL under the control of the control circuit 80. For example, the source line driver 60 may receive a voltage for driving the source line SL from the control circuit 80.

The input/output circuit 70 may transmit the write data I/O DATA input from an external source to the write driver 40 and output the read data I/O DATA input from the sensing circuit 50 to the external source.

The control circuit 80 may control all operations of the magnetic memory device. For example, the control circuit 80 may control the row selection/driving circuit 20, the column selection circuit 30, the write driver 40, the sensing circuit 50, the source line driver 60, the input/output circuit 70, etc. In one example, the control circuit 80 may operate in response to a command CMD or control signals input from an external source. The command CMD may include a read command, a write command, etc.

FIG. 3 is an example circuit diagram for illustrating a magnetic memory device according to some embodiments.

Referring to FIG. 3, the memory cell array 10 may include a plurality of memory cells MC and OTPC arranged along a row direction and a column direction. The plurality of memory cells MC and OTPC may include a plurality of memory unit cells MC and a plurality of OTP unit cells OTPC.

The plurality of memory unit cells MC may be connected to the first word lines WL1, the bit lines BL, and the source lines SL. Each memory unit cell MC may include the first magnetic tunnel junction element MTJ1 and a first cell transistor CT11 and CT12.

The memory unit cell MC can be programmed multiple times. The memory unit cell MC may be switched to two resistance states under an electrical pulse applied to the first magnetic tunnel junction element MTJ1. The memory unit cell MC may be used as an MRAM.

In some embodiments, the memory unit cell MC may have a structure in which a plurality of cell transistors CT11 and CT12 are connected to one magnetic tunnel junction element MTJ1. For example, the memory unit cell MC may include two cell transistors CT11 and CT12. The number of cell transistors included in the memory unit cell MC is not limited thereto and may vary.

One end of the first magnetic tunnel junction element MTJ1 may be connected to the bit line BL, and the other end of the first magnetic tunnel junction element MTJ1 may be connected to one end of the (1-1)-st cell transistor CT11 and one end of the (1-2)-nd cell transistor CT12. The other end of the (1-1)-st cell transistor CT11 and the other end of the (1-2)-nd cell transistor CT12 are connected to the source line SL. A gate electrode of the (1-1)-st cell transistor CT11 and a gate electrode of the (1-2)-nd cell transistor CT12 may be connected to the first word line WL1. The (1-1)-st cell transistor CT11 and the (1-2)-nd cell transistor CT12 may be turned on or off based on a signal or voltage provided thereto via the first word line WL1.

The plurality of OTP unit cells OTPC may be connected to the second to fourth word lines WL21, WL31, and WL41, the bit lines BL, and the source lines SL. Each OTP unit cell OTPC may include the second magnetic tunnel junction element MTJ2, a second cell transistor CT21 and CT22, a third magnetic tunnel junction element MTJ3, a third cell transistor CT31 and CT32, a fourth magnetic tunnel junction element MTJ4, and a fourth cell transistor CT41 and CT42.

The OTP unit cell OTPC can be programmed only once. The programmed second magnetic tunnel junction element MTJ2 may have an irreversible resistance state. The OTP unit cell OTPC may be used as the OTP memory.

According to some embodiments, the OTP unit cell OTPC may have a structure in which a plurality of cell transistors CT21, CT22, CT31, CT32, CT41, and CT42 are connected to one magnetic tunnel junction element MTJ2. For example, the OTP unit cell OTPC may include six cell transistors CT21, CT22, CT31, CT32, CT41, and CT42. The second cell transistor CT21 and CT22, the third cell transistor CT31 and CT32, and the fourth cell transistor CT41 and CT42 may be connected to each other in parallel. The number of cell transistors included in the OTP unit cell OTPC is not limited thereto and may vary.

One end of the second magnetic tunnel junction element MTJ2 may be connected to the bit line BL, and the other end of the second magnetic tunnel junction element MTJ2 may be connected to one end of the (2-1)-st cell transistor CT21 and one end of the (2-2)-nd cell transistor CT22. The other end of the (2-1)-st cell transistor CT21 and the other end of the (2-2)-nd cell transistor CT22 are connected to the source line SL. A gate electrode of the (2-1)-st cell transistor CT21 and a gate electrode of the (2-2)-nd cell transistor CT22 may be connected to the second word line WL21. The (2-1)-st cell transistor CT21 and the (2-2)-nd cell transistor CT22 may be turned on or off based on a signal or voltage provided thereto via the second word line WL21.

One end of the third magnetic tunnel junction element MTJ3 may be connected to the bit line BL. The other end of the third magnetic tunnel junction element MTJ3 is not connected to one end of the (3-1)-st cell transistor CT31 and one end of the (3-2)-nd cell transistor CT32, and the third magnetic tunnel junction element MTJ3 is electrically isolated from the third cell transistor CT31 and CT32. One end of the (3-1)-st cell transistor CT31 and one end of the (3-2)-nd cell transistor CT32 are connected to the other end of the second magnetic tunnel junction element MTJ2. The other end of the (3-1)-st cell transistor CT31 and the other end of the (3-2)-nd cell transistor CT32 are connected to the source line SL. A gate electrode of the (3-1)-st cell transistor CT31 and a gate electrode of the (3-2)-nd cell transistor CT32 may be connected to the third word line WL31. The (3-1)-st cell transistor CT31 and the (3-2)-nd cell transistor CT32 may be turned on or off based on a signal or voltage provided thereto via the third word line WL31.

One end of the fourth magnetic tunnel junction element MTJ4 may be connected to the bit line BL, and the other end of the fourth magnetic tunnel junction element MTJ4 is not connected to one end of the (4-1)-st cell transistor CT41 and one end of the (4-2)-nd cell transistor CT42. The fourth magnetic tunnel junction element MTJ4 is electrically isolated from the fourth cell transistors CT41 and CT42. One end of the (4-1)-st cell transistor CT41 and one end of the (4-2)-nd cell transistor CT42 are connected to the other end of the second magnetic tunnel junction element MTJ2. The other end of the (4-1)-st cell transistor CT41 and the other end of the (4-2)-nd cell transistor CT42 are connected to the source line SL. A gate electrode of the (4-1)-st cell transistor CT41 and a gate electrode of the (4-2)-nd cell transistor CT42 may be connected to the fourth word line WL41. The (4-1)-st cell transistor CT41 and the (4-2)-nd cell transistor CT42 may be turned on or off based on a signal or voltage provided thereto via the fourth word line WL41.

The third and fourth magnetic tunnel junction elements MTJ3 and MTJ4 may be dummy magnetic tunnel junction elements. The third and fourth magnetic tunnel junction elements MTJ3 and MTJ4 may be unused magnetic tunnel junction elements.

The pair of the second magnetic tunnel junction element MTJ2 and the second cell transistor CT21 and CT22, the pair of the third magnetic tunnel junction element MTJ3 and the third cell transistor CT31 and CT32, and the pair of the fourth magnetic tunnel junction element MTJ4 and the fourth cell transistor CT41 and CT42 of the OTP unit cell OTPC, and the pair of the first magnetic tunnel junction element MTJ1 and the first cell transistor CT11 and CT12 of the memory unit cell MC may be arranged in the memory cell array 10 so as to constitute a repetition unit.

Each of the first to fourth cell transistors CT11, CT12, CT21, CT22, CT31, CT32, CT41, and CT42 may include at least one of, for example, a diode, a PNP bipolar transistor, an NPN bipolar transistor, an NMOS field effect transistor, and a PMOS field effect transistor.

In some embodiments, the memory cell array 10 may include a first area R1 used as MRAM and a second area R2 used as the OTP memory. A plurality of memory unit cells MC are arranged in the first area R1, and a plurality of OTP unit cells OTPC are arranged in the second area R2.

In some embodiments, memory unit cells MC constituting one column and memory unit cells MC constituting another column may share one source line SL. OTP unit cells OTPC constituting one column and OTP unit cells OTPC constituting another column may share one source line SL. The technical concept of the present disclosure is not limited thereto. Although not shown in detail, for example, the OTP unit cells OTPC constituting one column and the OTP unit cells OTPC constituting another column may not share one source line SL and may be connected to separate source lines.

In some embodiments, a read path and a write path of the OTP unit cell OTPC may be isolated from each other. Some of the second to fourth cell transistors CT21, CT22, CT31, CT32, CT41 and C42 of the OTP unit cell OTPC may be used during a read operation of the OTP unit cell OTPC, and the remainder thereof may be used during a write operation of the OTP unit cell OTPC.

For example, the second cell transistor CT21 and CT22 connected to the second word line WL21 may be used during the read operation of the OTP unit cell OTPC, and the third cell transistor CT31 and CT32 connected to the third word line WL31 and the fourth cell transistor CT41 and CT42 connected to the fourth word line WL41 may be used during the write operation of the OTP unit cell OTPC.

For example, the third word line WL31 and the fourth word line WL41 may be connected to each other. The third word line WL31 and the fourth word line WL41 may be the same word line. The gate of the third cell transistor CT31 and CT32 and the gate of the fourth cell transistor CT41 and CT42 may operate based on the same word line voltage and may operate based on a different word line voltage from a word line voltage based on which the gate of the second cell transistor CT21 and CT22 operates.

Alternatively, the second to fourth word lines WL21, WL31, and WL41 may be different word lines. The gate of the second cell transistor CT21 and CT22, the gate of the third cell transistor CT31 and CT32, and the gate of the fourth cell transistor CT41 and CT42 may operate based on different word line voltages.

In some embodiments, the read path and the write path of the OTP unit cell OTPC may not be isolated from each other. The second to fourth cell transistors CT21, CT22, CT31, CT32, CT41 and C42 of the OTP unit cell OTPC may be used during both the read and write operations of the OTP unit cell OTPC.

The memory cell array 10 may be electrically connected to a peripheral circuit. The peripheral circuit may include, for example, the row selection/driving circuit 20, the column selection circuit 30, the write driver 40, the sensing circuit 50, the source line driver 60, the input/output circuit 70, and the control circuit 80 of FIG. 2. The memory unit cells MC and the OTP unit cells OTP may be electrically connected to the peripheral circuit. That is, the memory unit cells MC and the OTP unit cells OTP may share the peripheral circuit.

In some embodiments, the OTP unit cells OTPC may be connected to specific word lines (e.g., the second to fourth word lines WL21, WL31, and WL41).

In the first area R1, the first word lines WL and memory unit cells MC connected to the first word lines WL may be disposed. In the second area R2, the second to fourth word lines WL21, WL31, and WL41, and OTP unit cells OTPC connected to the second to fourth word lines WL21, WL31, and WL41 may be disposed. Only memory unit cells MC may be connected to the first word line WL, and only OTP unit cells OTPC may be connected to the second to fourth word lines WL21, WL31, and WL41. The memory unit cells MC and the OTP unit cells OTPC may be connected to one bit line BL.

The arrangement of the first area R1 and the second area R2 within the memory cell array 10 may vary. For example, the second area R2 may constitute an edge area of the memory cell array 10. The OTP unit cells OTPC may be connected to the second to fourth word lines WL21, WL31, and WL41 disposed in the edge area of the memory cell array 10.

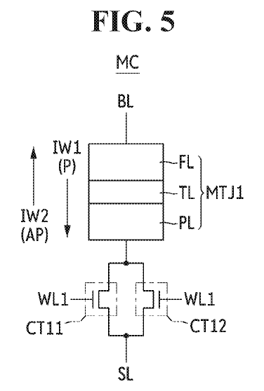

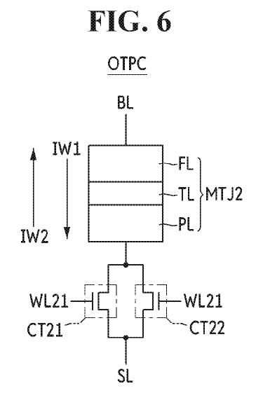

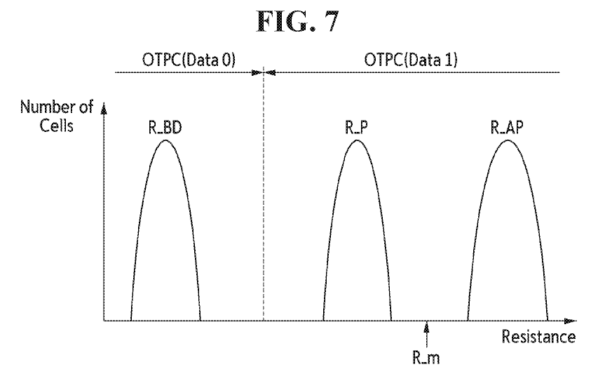

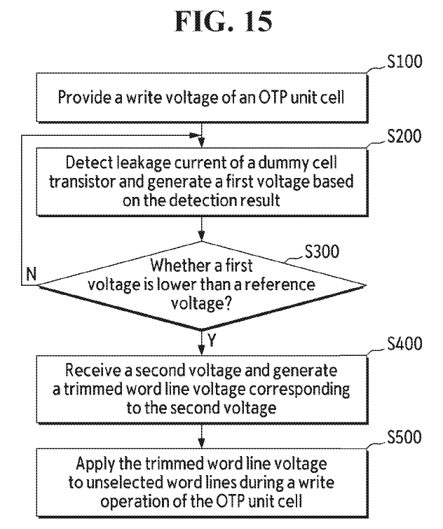

FIG. 4 is an example diagram for illustrating a magnetic memory device according to some embodiments. FIG. 5 is an example circuit diagram for illustrating a memory unit cell according to some embodiments. FIG. 6 is an example circuit diagram for illustrating an OTP unit cell according to some embodiments. FIG. 7 is a diagram for illustrating resistances of a memory unit cell and an OTP unit cell according to some embodiments. FIG. 15 is a flowchart illustrating a method for operating a magnetic memory device according to some embodiments.

Referring to FIG. 4, the row selection/driving circuit 20 may select one of a word line WLk to WLn connected to a memory cell on which a read operation or a program operation is to be performed, where k may be an integer of 1 or greater, and n may be an integer of 2 or greater and is greater than k. The row selection/driving circuit 20 may apply a word line voltage input from the control circuit 80 to the selected word line. In addition, the row selection/driving circuit 20 may apply a trimmed (e.g., adjusted or calibrated) word line voltage NWL received from the control circuit 80 to an unselected word line, as described below.

The control circuit 80 may include a dummy cell array 81, a voltage providing unit, a current-to-voltage converter 83, a comparator 84, and a word line voltage generator 85. The dummy cell array 81 may include a plurality of dummy cells DC. The plurality of dummy cells DC may be arranged in an array form. For example, each of the plurality of dummy cells DC may have the same structure as that of the memory unit cell MC and the OTP unit cell OTPC of the memory cell array 10. However, embodiments of the present disclosure are not limited thereto. A detailed structure of each of the plurality of dummy cells DC will be described later.

The memory unit cell MC may be connected to a specific word line (e.g., a k-th word line WLk). The memory unit cell MC connected to the specific word line (e.g., a k-th word line WLk) may be connected to the bit line BL. The specific word line (e.g., the k-th word line WLk) may correspond to the first word line WL1 of FIG. 3.

The memory unit cell MC may have a structure in which at least one or more memory cell transistors CT11 and CT12 are connected to one magnetic tunnel junction element MTJ1. For example, one end of the magnetic tunnel junction element MTJ1 may be connected to a bit line BL, and the other end of the magnetic tunnel junction element MTJ1 may be connected to one end of each of the memory cell transistors CT11 and CT12. A gate electrode of each of the memory cell transistors CT11 and CT12 may be connected to the k-th word line WLk. The memory cell transistors CT11 and CT12 may be turned on or off based on a signal (or voltage) provided via the k-th word line WLk.

The OTP unit cell OTPC may be connected to a specific word line (e.g., an n-th word line WLn). The OTP unit cell OTPC connected to a specific word line (e.g., the n-th word line WLn) may be connected to the bit line BL. The specific word line (e.g., the n-th word line WLn) may correspond to the second word line WL21 of FIG. 3.

The OTP unit cell OTPC may have a structure in which a plurality of cell transistors CT21 and CT22 are connected to one magnetic tunnel junction element MTJ 2. For example, one end of the magnetic tunnel junction element MTJ2 is connected to a bit line BL, and the other end of the magnetic tunnel junction element MTJ2 is connected to one end of each of the plurality of cell transistors CT21 and CT22. A gate electrode of each of the plurality of cell transistors CT21 and CT22 may be connected to the n-th word line WLn. Each of the plurality of cell transistors CT21 and CT22 may be turned on or off based on a signal (or voltage) provided via the n-th word line WLn.

The first magnetic tunnel junction element MTJ1 of the memory unit cell MC may include a pinned layer PL, a tunnel layer TL, and a free layer FL. The tunnel layer TL may be interposed between the pinned layer PL and the free layer FL.

The pinned layer PL may have a fixed magnetization direction regardless of the external magnetic field, and the free layer FL may have a magnetization direction that may be changed to be parallel or anti-parallel to the magnetization direction of the pinned layer PL.

The first magnetic tunnel junction element MTJ1 may store data in the memory unit cell MC using a difference in electrical resistance, according to the magnetization direction of the pinned layer PL and the magnetization direction of the free layer FL.

For a write operation of the memory unit cell MC, a turn-on voltage may be applied to the first word line WL1, and a write voltage may be applied across the first magnetic tunnel junction element MTJ1. A first write current IW1 or a second write current IW2 may flow through the first magnetic tunnel junction element MTJ1 according to a direction of the write voltage applied across the first magnetic tunnel junction element MTJ1.

For example, when a relatively high voltage (e.g., a write voltage) is applied to the bit line BL and a relatively low voltage (e.g., a ground voltage) is applied to the source line SL, the first write current IW1 flowing from the bit line BL to the source line SL may be provided to the first magnetic tunnel junction element MTJ1. In this case, electrons having the same spin direction as that of the pinned layer PL may tunnel through the tunnel layer TL to apply torque to the free layer FL. Accordingly, the first magnetic tunnel junction element MTJ1 may be in a parallel state P in which the magnetization direction of the free layer FL is parallel to the magnetization direction of the pinned layer PL, and the first magnetic tunnel junction element MTJ1 may have a first resistance value R_P and store therein data 0. That is, the data corresponding to the parallel state P may be written in the memory unit cell MC using the first write current IW1.

When a relatively high voltage (e.g., the write voltage) is applied to the source line SL and a relatively low voltage (e.g., a ground voltage) is applied to the bit line BL, the second write current IW2 flowing from the source line SL to the bit line BL may be provided to the first magnetic tunnel junction element MTJ1. In this case, electrons having a spin direction opposite to that of the pinned layer PL may not tunnel through the tunnel layer TL and may be reflected to the free layer FL to apply a torque to the free layer FL. Accordingly, the first magnetic tunnel junction element MTJ1 may be changed to the anti-parallel state AP in which the magnetization direction of the free layer FL may be anti-parallel to the magnetization direction of the pinned layer PL, and the first magnetic tunnel junction element MTJ1 may have a second resistance value R_AP and may store data 1 therein. The second resistance value R_AP may be greater than the first resistance value R_P. That is, the data corresponding to the anti-parallel state AP may be written in the memory unit cell MC using the second write current IW2.

That is, the memory unit cell MC may have the first resistance value R_P or the second resistance value R_AP based on the direction of each of the write currents IW1 and IW2 flowing through the first magnetic tunnel junction element MTJ1, and thus may be implemented as a memory cell which is programmable a plurality of times.

A reference resistance value R_m for a read operation of the memory unit cell MC may be determined. The reference resistance value R_m may have a value between the first resistance value R_P and the second resistance value R_AP.

Although it is illustrated that the free layer FL is connected to the bit line BL and the pinned layer PL is connected to the first cell transistor CT11 and CT12, the present disclosure is not limited thereto. In some embodiments, the pinned layer PL may be connected to the bit line BL and the free layer FL may be connected to the first cell transistor CT11 and CT12.

In some embodiments, each of the pinned layer PL and the free layer FL may have a magnetization easy axis in a direction perpendicular to an interface between the pinned layer PL and the free layer FL.

Each of the pinned layer PL and the free layer FL may include at least one of a perpendicular magnetic material (e.g., CoFeTb, CoFeGd, and CoFeDy), a perpendicular magnetic material having an L1₀ structure, a CoPt having a hexagonal close packed lattice structure, and a perpendicular magnetic structure. The perpendicular magnetic material having the L1₀ structure may include, for example, FePt having a L1₀ structure, FePd having a L1₀ structure, CoPd having a L1₀ structure, CoPt having a L1₀ structure, etc. The perpendicular magnetic structure may include magnetic layers and non-magnetic layers that are alternately and repeatedly stacked on top of each other. For example, the perpendicular magnetic structure may include (Co/Pt)ₙ, (CoFe/Pt)ₙ, (CoFe/Pd)ₙ, (Co/Pd)ₙ, (Co/Ni)ₙ, (CoNi/Pt)ₙ, (CoCr/Pt)ₙ or (CoCr/Pd)ₙ (where n is the number of stacks).

In some embodiments, each of the pinned layer PL and the free layer FL may have a magnetization easy axis in a direction horizontal to an interface between the pinned layer PL and the free layer FL.

Each of the pinned layer PL and the free layer FL may include a ferromagnetic material. In some embodiments, the pinned layer PL may further include an antiferromagnetic material for fixing the magnetization direction of the ferromagnetic material. For example, the ferromagnetic material may include at least one of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂. For example, the antiferromagnetic material may include at least one of PtMn, IrMn, MnO, MnS, MnTe, MnF₂, FeCl₂, FeO, CoCl₂, CoO, NiCl₂, NiO, and Cr, or at least one selected from a precious metal. The precious metal may include ruthenium (Ru), rhodium (Rh), palladium (Pd), osmium (Os), iridium (Ir), platinum (Pt), gold (Au), or silver (Ag). The free layer FL may be composed of a plurality of layers.

The tunnel layer TL may include, for example, at least one selected from oxides of magnesium (Mg), titanium (Ti), aluminum (Al), magnesium-zinc (MgZn) and magnesium-boron (MgB), and nitrides of titanium (Ti) and vanadium (V).

Referring to FIGS. 5 and 6, the OTP unit cell OTPC may have a structure similar to that of the memory unit cell MC. For reference, in FIG. 6, the third cell transistors CT31 and CT32 connected to the third word line WL31 and the fourth cell transistors CT41 and CT42 connected to the fourth word line WL41 are omitted.

The second magnetic tunnel junction element MTJ2 of the OTP unit cell OTPC may include a pinned layer PL, a tunnel layer TL, and a free layer FL. The tunnel layer TL may be interposed between the pinned layer PL and the free layer FL. The pinned layer PL, the tunnel layer TL, and the free layer FL of the second magnetic tunnel junction element MTJ2 may be made of the same materials as those of the pinned layer PL, the tunnel layer TL, and the free layer FL of the first magnetic tunnel junction element MTJ1, respectively.

Each of some of the OTP unit cells OTPC may be in a state in which the second magnetic tunnel junction element MTJ2 is in an insulation-broken down state, and each of the rest of the OTPC cells OTPC may be in a state in which the second magnetic tunnel junction element MTJ2 is not in an insulation-broken down state.

In each of some of the OTP unit cells OTPC, a breakdown voltage may be applied across the second magnetic tunnel junction element MTJ2 via one program operation, and the tunnel layer TL of the second magnetic tunnel junction element MTJ2 may be insulation-broken down. Each of some of the OTP unit cells OTPC may have an irreversible resistance state. A breakdown current may flow through the second magnetic tunnel junction element MTJ 2 under the breakdown voltage. The breakdown current may be greater than each of the first and second write currents IW1 and IW2. The second magnetic tunnel junction element MTJ2 that is insulation-broken down may be in a short-circuited state. The second magnetic tunnel junction element MTJ2 that is insulation-broken down may have a third resistance value R_BD and may store data 0 therein. The second magnetic tunnel junction element MTJ2 that is not insulation-broken down may have a resistance value greater than the third resistance value R_BD and store data 1 therein. The second magnetic tunnel junction element MTJ2, which is not insulation-broken down, may be in the parallel state P or the anti-parallel state AP.

That is, the OTP unit cell OTPC may be programmed only once, may have a state in which the tunnel layer TL is in an insulation-broken down state or in a state in which the tunnel layer TL is not in an insulation-broken down state.

As described above, for a write operation of the memory unit cell MC, a high voltage (e.g., a write voltage) may be applied to the bit line BL and a low voltage (e.g., a ground voltage) may be applied to the source line SL, or a high voltage (e.g., the write voltage) may be applied to the source line SL and a low voltage (e.g., a ground voltage) may be applied to the bit line BL. The write voltage is applied to the bit line BL, the first magnetic tunnel junction element MTJ1, the cell transistors CT11 and CT12, the source line SL, etc., in a divided manner.

In some embodiments, the breakdown voltage is applied across the second magnetic tunnel junction element MTJ 2 for the write operation of the OTP unit cell OTPC, and the magnitude of the write voltage applied for the write operation of the OTP unit cell OTPC is greater than the magnitude of the write voltage applied for the write operation of the memory unit cell MC.

For example, when the memory unit cell MC and the OTP unit cell OTPC share the bit line BL, the source line SL, and the peripheral circuit with each other, a high write voltage may be applied to the unselected cell transistor on which a program operation is not performed.

In this case, a leakage current of the unselected cell transistor may be excessively increased, and thus the performance of the element may be deteriorated. Furthermore, the sizes of other components of the peripheral circuit required to cope with the above problem may increase, and thus the size of an entirety of the element may be excessively increased.

The row selection/driving circuit 20 of the magnetic memory device according to some embodiments may apply the trimmed word line voltage NWL from the control circuit 80 to the unselected word line. Accordingly, when a write operation of the OTP unit cell OTPC is performed, a leakage current due to a high voltage being provided to the drain of the non-selected cell transistor via the bit line may be reduced. An operation in which the control circuit 80 generates the trimmed word line voltage NWL will be described later.

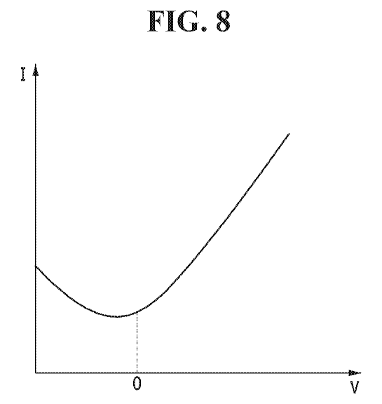

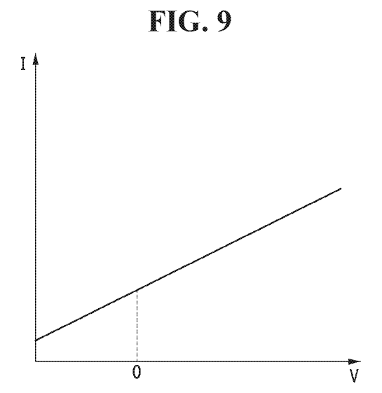

FIGS. 8 and 9 are schematic diagrams for illustrating GIDL characteristics of a magnetic memory device according to some embodiments.

FIG. 8 is a diagram for illustrating GIDL characteristics of a cell transistor of an OTP unit cell OTPC when a write operation is performed on the OTP unit cell OTPC. In this case, the write voltage applied through the bit line BL may be, for example, 1 V or greater. FIG. 9 is a diagram illustrating characteristics of a cell transistor of a memory unit cell MC or an OTP unit cell OTPC when a voltage applied through a bit line is a read voltage level (e.g., lower than 0.1V). In the graphs of FIGS. 8 and 9, a horizontal axis represents the word line voltage V, and a vertical axis represents a drain current I.

As described above, the magnitude of the write voltage applied through the bit line BL for the write operation of the OTP unit cell OTPC may be greater than the magnitude of the read voltage. Accordingly, in the cell transistor of the OTP unit cell OTPC in which the write operation is performed, the potential difference between the gate and the drain increases, thereby increasing the GIDL. In addition, even in the cell transistor of each of the OTP unit cell OTPC and the memory unit cell MC in which the write operation is not performed (i.e., connected to the unselected word line), the potential difference between the gate and the drain increases, and thus the GIDL increases.

Referring to FIG. 8, when a write operation is performed on the OTP unit cell OTPC, GIDL may increase as the word line voltage increases in a negative direction, and decrease as the word line voltage increases in a positive direction. The GIDL has a minimum value at a point where the word line voltage is about 0 V.

Referring to FIG. 9, the magnitude of the voltage applied through the bit line BL is smaller than that of FIG. 8, and the leakage current I decreases as the word line voltage V increases in the negative direction. For example, when a read operation is performed on the OTP unit cell OTPC, the leakage current I may be reduced by applying a word line voltage of about -0.3V to the word line of the cell transistor of each of the OTP unit cell OTPC and the unselected memory unit cell MC.

According to some embodiments, when a read operation is performed on the OTP unit cell OTPC, when a read operation is performed on the memory unit cell MC, or when a write operation is performed on the memory unit cell MC, a word line voltage of about -0.3 V may be applied to a word line of a cell transistor of an OTP unit cell OTPC or unselected memory unit cell MC. When a write operation is performed on the OTP unit cell OTPC, a word line voltage of about 0 V may be applied to a word line of a cell transistor of an OTP unit cell OTPC or the unselected memory unit cell MC.

That is, when a write operation is performed on the OTP unit cell OTPC, the word line voltage may be shifted in a relatively positive direction (e.g., from -0.3 V to 0 V) to reduce GIDL in the cell transistor of each of the OTP unit cell OTPC and the memory unit cell MC connected to the unselected word line.

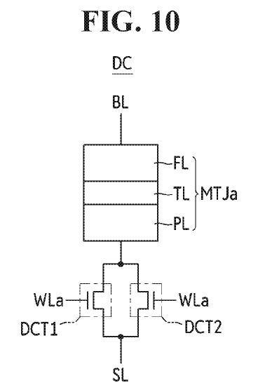

FIG. 10 is an example circuit diagram for illustrating a dummy cell according to some embodiments.

Referring to FIG. 10, a dummy cell DC may have substantially the same structure as that of at least one of the OTP unit cell OTPC and the memory unit cell MC. The dummy cell DC may be connected to a specific word line (e.g., an a-th word line WLa). The specific word line (e.g., the a-th word line WLa) may be one of the k-th to n-th word lines WLk to WLn.

The dummy cell DC may be connected to the bit line BL. The bit line BL to which the dummy cell DC is connected may be a bit line different from the bit line BL to which the memory unit cell MC and the OTP unit cell OTPC are connected.

The dummy cell DC may be connected to the source line SL. The source line SL to which the dummy cell DC is connected may be a source line different from the source line SL to which the memory unit cell MC and the OTP unit cell OTPC are connected.

A magnetic tunnel junction element MTJa of the dummy cell DC may include a pinned layer PL, a tunnel layer TL, and a free layer FL. The tunnel layer TL may be interposed between the pinned layer PL and the free layer FL. The pinned layer PL, the tunnel layer TL, and the free layer FL of the magnetic tunnel junction element MTJa may be made of the same materials as those of the pinned layer PL, the tunnel layer TL, and the free layer FL of the first magnetic tunnel junction element MTJ1, respectively.

The dummy cell DC may have a structure in which at least one dummy cell transistor DCT1 and DCT2 is connected to one magnetic tunnel junction element MTJa. For example, one end of the magnetic tunnel junction element MTJa may be connected to a bit line BL, and the other end of the magnetic tunnel junction element MTJa may be connected to one end of the dummy cell transistors DCT1 and DCT2. Gate electrodes of the dummy cell transistors DCT1 and DCT2 may be connected to an a-th word line WLa. The dummy cell transistors DCT1 and DCT2 may be turned on or off based on a signal (or voltage) provided through the a-th word line WLa.

Hereinafter, a method for operating a magnetic memory device according to some embodiments will be described with reference to FIGS. 4 and 15.

First, the control circuit 80 may provide a control signal to the row selection/driving circuit 20. The control signal can prevent all the word lines WLk to WLn connected to the memory cell array 10 from being selected. Accordingly, the word line voltage may not be applied to any one of the word lines WLk to WLn connected to the memory cell array 10. The control circuit 80 may generate a trimmed word line voltage NWL to be described later in a state in which the word line voltage is not applied to the word lines WLk to WLn.

Thereafter, the voltage providing unit may provide a voltage to the dummy cell array 81. The voltage providing unit may include a transistor TR configured to apply a fixed potential. The voltage providing unit may provide a write voltage VBL of the OTP unit cell OTPC in S100. In some embodiments, the configuration of the voltage providing unit is not limited to the above description.

Thereafter, the current-to-voltage converter 83 may generate a first voltage VIN based on the leakage current GIDL of the dummy cell transistor. The current-to-voltage converter 83 may detect the leakage current GIDL of the dummy cell transistor and generate the first voltage VIN based on the detection result in S200. The leakage current GIDL may be detected from the dummy cell array 81. That is, the dummy cell array 81, the voltage providing unit, the current-to-voltage converter 83, and the comparator 84 may constitute a leakage current (GIDL) detector.

The first voltage VIN generated by the current-to-voltage converter 83 may be provided to a first input terminal of the comparator 84. A reference voltage VREF may be provided to a second input terminal of the comparator 84.

For example, the row selection/driving circuit 20 may select a word line (e.g., WLn) of a specific row corresponding to a specific OTP unit cell OTPC and may not select other word lines (e.g., WLk to WLn-1) in order to perform a write operation of the OTP unit cell OTPC.

The reference voltage VREF may be set based on an allowable GIDL of the cell transistors of the OTP unit cell OTPC and the cell transistors of the memory unit cell MC connected to the unselected word lines (e.g., WLk to WLn-1). That is, the reference voltage VREF may refer to a voltage corresponding to an allowable minimum leakage current GIDL of cell transistors of the OTP unit cell OTPC and cell transistors of the unselected memory unit cell MC.

Thereafter, the comparator 84 may compare the reference voltage VREF with the first voltage VIN, and may output the first voltage VIN which is smaller than the reference voltage VREF, as a second voltage VOUT in S300. That is, when the GIDL is reduced to an allowable level or lower, the comparator 84 may stop the comparison operation and output the second voltage VOUT.

Thereafter, the word line voltage generator 85 may receive the second voltage VOUT from the comparator 84 and generate the trimmed word line voltage NWL corresponding to the second voltage VOUT in S400. That is, the word line voltage NWL may be a voltage trimmed based on the second voltage VOUT. The word line voltage NWL may vary based on a potential difference between a gate and a drain of a cell transistor of the OTP unit cell OTPC. The word line voltage generator 85 may generate a trimmed word line voltage NWL such that GIDL of cell transistors connected to unselected word lines (e.g., WLk to WLn-1) has an allowable minimum value. For example, the trimmed word line voltage NWL may vary depending on a write voltage, characteristics (e.g., temperature conditions) of cell transistors, etc. during a write operation of the OTP unit cell OTPC.

The trimmed word line voltage NWL may be a voltage different from a word line voltage when a read operation of the OTP unit cell OTPC is performed, a word line voltage when a write operation of the memory unit cell MC is performed, or a word line voltage when a read operation of the memory unit cell MC is performed. That is, the trimmed word line voltage NWL may be a voltage having a potential different from a potential of a word line voltage applied to the OTP unit cell OTPC when a read operation of the OTP unit cell OTPC is performed, different from a potential of a word line voltage applied to the memory unit cell MC when a write operation of the memory unit cell MC is performed, or different from a potential of a word line voltage applied to the memory unit cell MC when a read operation of the memory unit cell MC is performed.

For example, the trimmed word line voltage NWL may be a voltage shifted in a positive direction relative to a word line voltage when a read operation of the OTP unit cell OTPC is performed, a word line voltage when a write operation of the memory unit cell MC is performed, or a word line voltage when a read operation of the memory unit cell MC is performed. For example, the trimmed word line voltage NWL may have a potential which is higher than that of the word line voltage when the read operation of the OTP unit cell OTPC is performed, but is lower than 0 V. Alternatively, for example, the word line voltage NWL may be 0 V. However, the technical idea of the present disclosure is not limited thereto.

Thereafter, the row selection/driving circuit 20 may receive the trimmed word line voltage NWL from the control circuit 80 and apply the same to unselected word lines (e.g., WLk to WLn-1) during a write operation of the OTP unit cell OTPC in S500. Accordingly, when the write operation of the OTP unit cell OTPC is performed, the leakage current GIDL of the unselected cell transistor may be reduced.

The above-described trimming of the word line voltage by the control circuit 80 may be performed only once before the write operation of the OTP unit cell OTPC is performed.

Thereafter, a read operation of the OTP unit cell OTPC may be performed. The word line voltage provided to the OTP unit cell OTPC during the read operation of the OTP unit cell OTPC may be different from the above-described trimmed word line voltage NWL.

An example in which the leakage current (GIDL) detection scheme according to some embodiments is embodied as a scheme of converting a current into a voltage and sensing/comparing the voltage is described. However, the technical concept of the present disclosure is not limited thereto. Although not shown in detail, the leakage current GIDL detection scheme according to some embodiments may be embodied as a scheme of sensing/comparing a current.

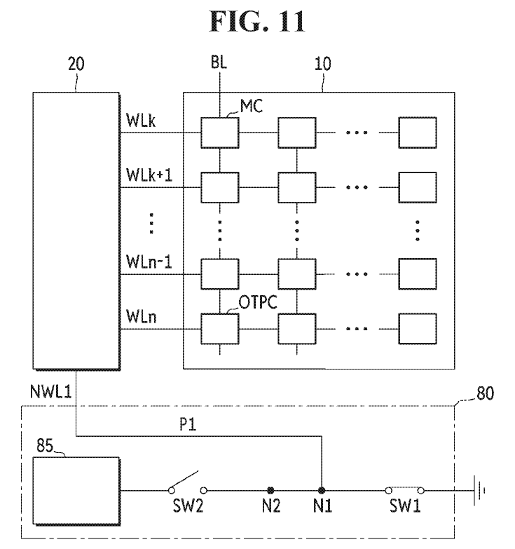

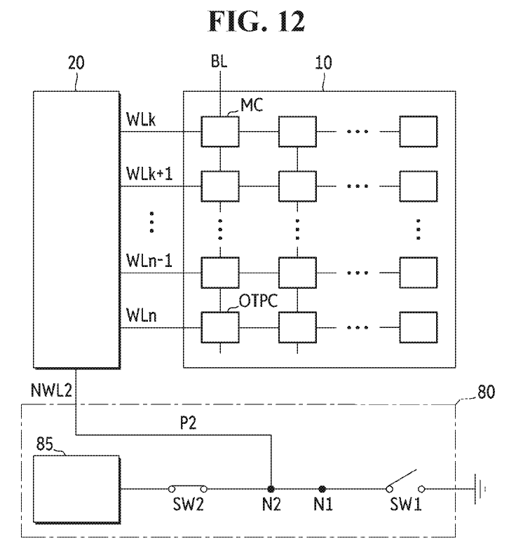

FIGS. 11 and 12 are example diagrams for illustrating a magnetic memory device according to some embodiments. For convenience of description, contents duplicate with those as described above with reference to FIGS. 1-10 will be briefly described or the descriptions thereof are omitted.

For reference, FIG. 11 is a diagram for illustrating an operation of the control circuit 80 when a write operation of the OTP unit cell OTPC is performed. For reference, FIG. 12 is a diagram for illustrating an operation of the control circuit 80 when a read operation of the OTP unit cell OTPC is performed.

The control circuit 80 may include a first switch SW1, a second switch SW2, and the word line voltage generator 85. Unlike the control circuit 80 of FIGS. 11 and 12, the control circuit 80 of FIGS. 11 and 12 does not include the dummy cell array 81 of FIG. 4, the voltage providing unit, the current-voltage converter 83 of FIG. 4, and the comparator 84 of FIG. 4.

Referring to FIG. 11, the control circuit 80 may generate a first switch control signal for turning on the first switch SW1. The first switch control signal may turn on the first switch SW1 and turn off the second switch SW2. When the first switch SW1 is turned on, the row selection/driving circuit 20 may be electrically connected to the ground via a first electrical path P1 connected to a first node N1. Although FIG. 11 illustrates that the row selection/driving circuit 20 is connected to the ground when the first switch SW1 is turned on, the voltage connected to the row selection/driving circuit 20 is not necessarily limited to the ground voltage.

During a write operation of the OTP unit cell OTPC, the row selection/driving circuit 20 may select a word line (e.g., WLn) of a specific row corresponding to the specific OTP unit cell OTPC and may not select other word lines (e.g., WLk to WLn-1). The control circuit 80 may generate a first word line voltage NWL1 to be applied to the unselected word lines (e.g., WLk to WLn-1). In this case, the first word line voltage NWL1 may be a fixed value of 0 V. However, the fixed value is not necessarily limited to 0 V.

Thereafter, the row selection/driving circuit 20 may receive the first word line voltage NWL1 from the control circuit 80 and apply the first word line voltage NWL1 to the unselected word lines (e.g., WLk to WLn-1) during a write operation of the OTP unit cell OTPC.

Referring to FIG. 12, the control circuit 80 may generate a second switch control signal SW2 for turning on the second switch SW2. The second switch control signal may turn on the second switch SW2 and turn off the first switch SW1. When the second switch SW2 is turned on, the row selection/driving circuit 20 may be electrically connected to the word line voltage generator 85 via a second electrical path P2 connected to a second node N2.

During a read operation of the OTP unit cell OTPC, the row selection/driving circuit 20 may select a word line (e.g., WLn) of a specific row corresponding to the specific OTP unit cell OTPC and may not select other word lines (e.g., WLk to WLn-1). The word line voltage generator 85 may generate a second word line voltage NWL2 to be applied to the unselected word lines (e.g., WLk to WLn-1). In this case, the second word line voltage NWL2 may have a potential different from that of the first word line voltage NWL1. For example, the second word line voltage NWL 2 may be about -0.3 V. However, embodiments of the present disclosure are not limited thereto.

Thereafter, the row selection/driving circuit 20 may receive the second word line voltage NWL2 from the control circuit 80 and apply the second word line voltage NWL2 to the unselected word lines (e.g., WLk to WLn-1) during a read operation of the OTP unit cell OTPC.

The control circuit 80 according to some embodiments may adjust the word line voltage to be provided to the unselected cell transistors, based on a comparison between performing a write operation on the OTP unit cell OTPC and performing a read operation on the OTP unit cell OTPC. Accordingly, the GIDL of the unselected cell transistors may be reduced, and the reliability of the element may be improved.

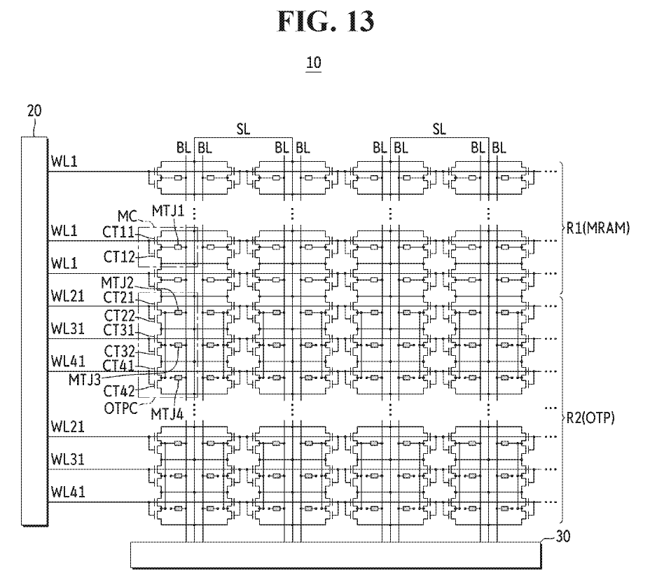

FIG. 13 is an example circuit diagram for illustrating a magnetic memory device according to some embodiments. For convenience of description, the contents duplicate those as described above with reference to FIGS. 1 -12 will be briefly described or the descriptions thereof are omitted.

Referring to FIG. 13, in some embodiments, four columns of the memory unit cells MC may share one source line SL. For example, memory unit cells MC constituting a first column, memory unit cells MC constituting a second column, memory unit cells MC constituting a third column, and memory unit cells MC constituting a fourth column may share one source line SL. The number of columns of the memory unit cells MC sharing one source line SL is not limited thereto, and five or more columns of the memory unit cells MC may share one source line SL.

The four columns of the OTP unit cells OTPC may share one source line SL. For example, the OTP unit cells OTPC constituting the first column, the OTP unit cells OTPC constituting the second column, the OTP unit cells OTPC constituting the third column, and the OTP unit cells OTPC constituting the fourth column may share one source line SL. The number of columns of the OTP unit cells OTPC sharing one source line SL is not limited thereto, and five or more columns of the OTP unit cells OTPC may share one source line SL.

For example, the number of columns of the memory unit cells MC sharing one source line SL may be equal to the number of columns of the OTP unit cells OTPC sharing one source line SL.

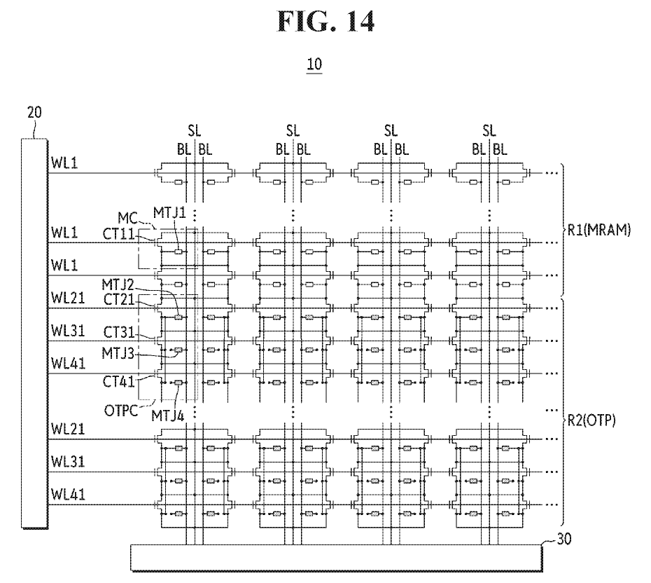

FIG. 14 is an example circuit diagram for illustrating a magnetic memory device according to some embodiments. For convenience of description, the contents duplicate those as described above with reference to FIGS. 1-13 will be briefly described or the descriptions thereof are omitted.

Referring to FIG. 14, in some embodiments, the memory unit cell MC may have a structure in which one cell transistor CT11 is connected to one magnetic tunnel junction element MTJ1. For example, the (1-2)-nd cell transistor CT12 of FIG. 3 may be omitted.

The OTP unit cell OTPC may have a structure in which three cell transistors CT21, CT31, and CT41 are connected to one magnetic tunnel junction element MTJ2. The second cell transistor CT21, the third cell transistor CT31, and the fourth cell transistor CT41 may be connected in parallel with each other. For example, the (2-2)-nd cell transistor CT22, the (3-2)-nd cell transistor CT32, and the (4-2)-nd cell transistor CT42 of FIG. 3 may be omitted.

A pair of the second magnetic tunnel junction element MTJ2 and the second cell transistor CT21, a pair of the third magnetic tunnel junction element MTJ3 and the third cell transistor CT31, and a pair of the fourth magnetic tunnel junction element MTJ4 and the fourth cell transistor CT41 of the OTP unit cell OTPC, and a pair of the first magnetic tunnel junction element MTJ1 and the first cell transistor CT11 of the memory unit cell MC may be arranged in the memory cell array 10 so as to constitute a repetition unit.

In the magnetic memory device of FIG. 13, the (1-2)-nd cell transistor CT12, the (2-2)-nd cell transistor CT22, the (3-2)-nd cell transistor CT32, and the (4-2)-nd cell transistor CT42 may be omitted.

Although embodiments of the present disclosure have been described above with reference to the accompanying drawings, the present disclosure may not be limited to embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that embodiments as described above are not restrictive but illustrative in all respects.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A method for operating a magnetic memory device, the method comprising:
applying a first word line voltage to a One-Time-Programmable (OTP) cell to perform a write operation on the OTP cell, wherein the OTP cell is connected to a first word line and a bit line, and includes a first magnetic tunnel junction element and an OTP cell transistor;
applying a second word line voltage to the OTP cell to perform a read operation on the OTP cell; and
applying a third word line voltage different from the second word line voltage to a plurality of second word lines different from the first word line, wherein performing the write operation is based on applying the third word line voltage.

2. The method of claim 1, wherein applying the third word line voltage to the plurality of second word lines occurs before performing the write operation.

3. The method of claim 1, wherein applying the third word line voltage to the plurality of second word lines includes:
providing a first voltage to a dummy cell, wherein the dummy cell includes a second magnetic tunnel junction element and a dummy cell transistor; and
generating a second voltage based on a gate-induced drain leakage (GIDL) of the dummy cell transistor.

4. The method of claim 3, wherein applying the third word line voltage to the plurality of second word lines includes comparing the second voltage with a reference voltage, and outputting the second voltage based on a comparison indicating that the second voltage is lower than the reference voltage as an output voltage,
wherein the reference voltage is based on a predetermined allowable GIDL of each OTP cell transistor of a plurality of OTP cell transistors connected to the plurality of second word lines.

5. The method of claim 4, wherein the third word line voltage is trimmed based on the output voltage.

6. The method of claim 1, wherein performing the read operation includes turning on a first switch to apply the second word line voltage to the plurality of second word lines.

7. The method of claim 6, wherein performing the write operation includes turning on a second switch to apply the third word line voltage to the plurality of second word lines.

8. The method of claim 7, comprising applying a third voltage to the plurality of second word lines based on turning on the second switch.

9. The method of claim 8, comprising applying a fourth voltage to the plurality of second word lines based on turning on the first switch, wherein the fourth voltage is different from the third voltage.

10. The method of claim 1, wherein the third word line voltage varies based on a potential difference between a gate and a drain of each OTP cell transistor of a plurality of OTP cell transistors connected to the plurality of second word lines.

11. The method of claim 1, wherein the third word line voltage is 0 V.

12. A method for operating a magnetic memory device, the method comprising:
applying a first word line voltage to a One-Time-Programmable (OTP) cell to perform a write operation on the OTP cell, wherein the OTP cell is connected to a selected word line among a plurality of word lines and a bit line, and includes a first magnetic tunnel junction element and an OTP cell transistor;
applying a second word line voltage to the OTP cell to perform a read operation on the OTP cell;
providing a first voltage to a dummy cell, wherein the dummy cell includes a second magnetic tunnel junction element and a dummy cell transistor;
applying a third word line voltage to unselected word lines different from the selected word line among the plurality of word lines, wherein the third word line voltage is a voltage trimmed based on a gate-induced drain leakage (GIDL) of the dummy cell transistor.

13. The method of claim 12, wherein applying the third word line voltage includes:
generating a second voltage based on the GIDL of the dummy cell transistor;
comparing the second voltage with a reference voltage and outputting the second voltage based on a comparison indicating that the second voltage is lower than the reference voltage as an output voltage; and
applying the third word line voltage based on the output voltage to the unselected word lines.

14. The method of claim 13, comprising setting the reference voltage based on a predetermined allowable GIDL of each OTP cell transistor of a plurality of OTP cell transistors connected to the unselected word lines.

15. The method of claim 12, wherein applying the third word line voltage to the unselected word lines is performed before performing the write operation.

16. The method of claim 12, wherein the third word line voltage is different from the second word line voltage.

17. A method for operating a magnetic memory device, the method comprising:
applying a first word line voltage to a One-Time-Programmable (OTP) cell to perform a write operation on the OTP cell, wherein the OTP cell is connected to a selected word line among a plurality of word lines and a bit line, and includes a first magnetic tunnel junction element and an OTP cell transistor; and
turning on a first switch to apply a second word line voltage to the OTP cell to perform a read operation on the OTP cell,
wherein performing the write operation includes:
turning on a second switch to generate a third word line voltage different from the second word line voltage; and
applying the third word line voltage to a plurality of unselected word lines different from the selected word line among the plurality of word lines.

18. The method of claim 17, comprising:
applying the second word line voltage to the plurality of unselected word lines via a first electrical path based on turning on the first switch; and,
applying the third word line voltage to the plurality of unselected word lines via a second electrical path based on turning on the second switch.

19. The method of claim 17, wherein when the first switch is turned on, the second switch is turned off, and
wherein when the second switch is turned on, the first switch is turned off.

20. The method of claim 17, wherein the third word line voltage has a fixed potential, and
wherein the second word line voltage has a different potential from the fixed potential of the third word line voltage.
